(19) United States
(12) Patent Application Publication
(10) Pub. No.: US 2025/0198941 A1
(43) Pub. Date: Jun. 19, 2025

(54) DEFECT INSPECTION SYSTEM AND DEFECT INSPECTION METHOD

(71) Applicant: Samsung Electronics Co., Ltd., Suwon-si (KR)

(72) Inventors: Min Ho RIM, Suwon-si (KR); Souk KIM, Suwon-si (KR); Young Hoon SOHN, Suwon-si (KR)

(21) Appl. No.: 18/924,455

(22) Filed: Oct. 23, 2024

(30) Foreign Application Priority Data
Dec. 19, 2023 (KR) 10-2023-0186001

(51) Int. Cl. G01N 21/88; G01N 21/3563; G01N 21/84

(52) U.S. Cl. CPC G01N 21/8851; G01N 21/3563; G01N 21/8422; G01N 21/8806; G01N 2021/3568; G01N 2021/8438; G01N 2021/8845; G01N 2021/8854

(57) ABSTRACT

A defect inspection system includes a stage configured to receive a measurement target thereon, wherein the measurement target includes a first layer and a second layer disposed under the first layer; and a defect inspection apparatus including: a light source unit configured to output first incident light and second incident light; a beam splitter configured to reflect the first incident light and the second incident light from the first light source to the measurement target, and transmit first reflected light and second reflected light therethrough, wherein the first reflected light corresponds to the first incident light reflected from the first layer and the second reflected light corresponds to the second incident light reflected from the second layer; an objective lens disposed between the beam splitter and the measurement target; and a detector configured to: detect the first reflected light and generate a first image of the first layer based on the detected first reflected light; and detect the second reflected light and generate a second image of the second layer based on the detected second reflected light, wherein the first incident light is included in a visible light band, and wherein the second incident light is included in an infrared light band.

### CROSS-REFERENCE TO RELATED APPLICATION

This application claims priority from Korean Patent Application No. 10-2023-0186001 filed on Dec. 19, 2023, in the Korean Intellectual Property Office, and all the benefits accruing therefrom under 35 U.S.C. 119, the contents of which in its entirety are herein incorporated by reference.

### BACKGROUND

### Field

The present disclosure relates to a defect inspection system and a manufacturing method using the defect inspection system and related methods.

### Description of Related Art

A semiconductor device is manufactured through various processes. As semiconductor design technology develops, the number of processes for manufacturing the semiconductor device increases and complexity of each of the processes increases. As the number and the complexity of the semiconductor manufacturing processes increase, various defects may be generated during the manufacturing process of the semiconductor device.

These defects may have a fatal impact on the semiconductor device. Therefore, detecting the defects is important.

### SUMMARY

A technical purpose of the present disclosure is to provide a defect inspection system with improved consistency.

Another technical purpose of the present disclosure is to provide a defect inspection method with improved consistency.

Technical benefits of the present disclosure are not limited to the above-mentioned purposes. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

According to an aspect of the present disclosure, a defect inspection system includes a stage configured to receive a measurement target thereon, wherein the measurement target includes a first layer and a second layer disposed under the first layer; and a defect inspection apparatus including a light source unit configured to output first incident light and second incident light; a beam splitter configured to reflect the first incident light and the second incident light from the first light source to the measurement target, and transmit first reflected light and second reflected light therethrough, wherein the first reflected light corresponds to the first incident light reflected from the first layer and the second reflected light corresponds to the second incident light reflected from the second layer; an objective lens disposed between the beam splitter and the measurement target; and a detector configured to: detect the first reflected light and generate a first image of the first layer based on the detected first reflected light; and detect the second reflected light and generate a second image of the second layer based on the detected second reflected light, wherein the first incident light is included in a visible light band, and wherein the second incident light is included in an infrared light band.

According to another aspect of the present disclosure, a defect inspection system includes a stage configured to receive a measurement target thereon, wherein the measurement target includes a first layer and a second layer disposed under the first layer; a defect inspection apparatus configured to scan a surface of the first layer using first incident light and generate a first image based on the scanning result, and to scan a surface of the second layer using second incident light and generate a second image based on the scanning result; and a controller configured to determine whether a defect of the measurement target is a first defect having occurred in the first layer or a second defect having occurred in a portion under the first layer, based on a first design image for the first layer, the first image, a second design image of the second layer, and the second image, wherein the first incident light and the second incident light have different wavelengths.

According to another aspect of the present disclosure, a method of manufacturing a semiconductor device fabricating a portion of a semiconductor device to generate a measurement target, acquiring a design image of the measurement target including a first layer and a second layer under the first layer, wherein the design image includes a first design image of the first layer and a second design image of the second layer; scanning the first layer using first incident light and generating a first image based on the scanning result, and scanning the second layer using second incident light and generating a second image based on the scanning result; performing an inspection to determine whether a defect of the measurement target is a first defect having occurred in the first layer or a second defect having occurred in the second layer, based on the first design image, the first image, the second design image, and the second image; and verifying the defects of the semiconductor device based on the results of the inspection.

Specific details of other embodiments are included in the detailed description and drawings.

### BRIEF DESCRIPTION OF DRAWINGS

The above and other aspects and features of the present disclosure will become more apparent by describing in detail some embodiments thereof with reference to the attached drawings, in which:

FIG. 1 is a diagram illustrating a defect inspection system according to some embodiments;

FIG. 2 is a diagram illustrating a cross section of a measurement target in FIG. 1;

FIG. 3 is a flowchart illustrating a defect inspection method according to some embodiments;

FIG. 4 is a diagram of a design image for describing the defect inspection method in FIG. 3;

FIG. 5 is a diagram of a design image for describing the defect inspection method in FIG. 3;

FIG. 6 is a flowchart illustrating S130 in FIG. 4;

FIG. 7 is a diagram for illustrating the defect inspection method in FIG. 6;

FIG. 8 is a diagram for illustrating the defect inspection method in FIG. 6;

FIG. 9 is a diagram for illustrating the defect inspection method in FIG. 6;

FIG. 10 is a diagram illustrating a defect inspection system according to some embodiments.

FIG. 11 is a diagram illustrating a defect inspection system according to some embodiments;

FIG. 12 is a diagram illustrating a defect inspection system according to some embodiments;

FIG. 13 is a flowchart illustrating a defect inspection method according to some embodiments;

FIG. 14 is a diagram for describing the defect inspection method in FIG. 13;

FIG. 15 is a diagram for describing the defect inspection method in FIG. 13;

FIG. 16 is a cross-sectional view for describing a semiconductor device manufacturing method according to some embodiments.

### DETAILED DESCRIPTIONS

The present disclosure now will be described more fully hereinafter with reference to the accompanying drawings, in which various embodiments are shown. The invention may, however, be embodied in many different forms and should not be construed as limited to the example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

In the following description, ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

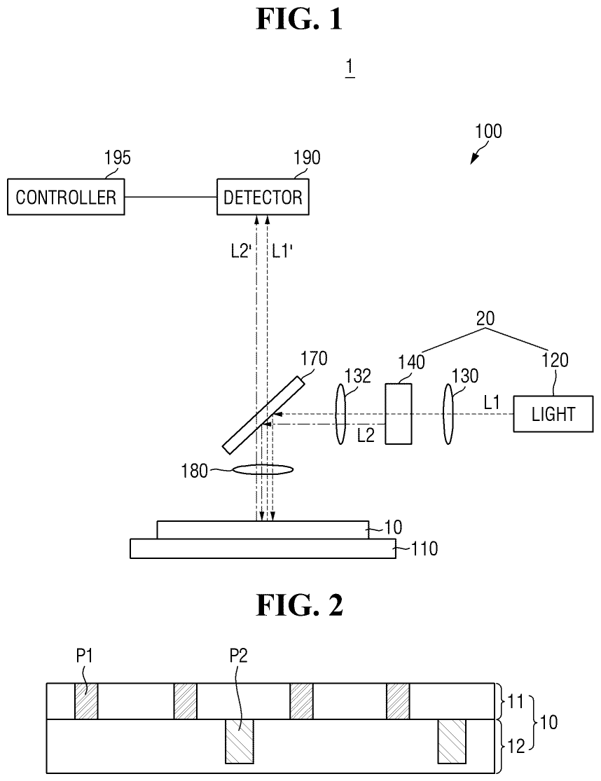

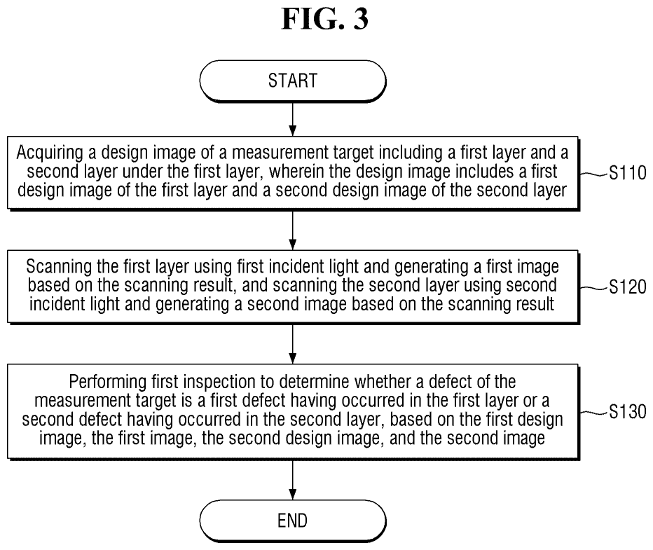

FIG. 1 is a diagram illustrating a defect inspection system according to some embodiments. FIG. 2 is a diagram illustrating an example of a measurement target in FIG. 1.

Referring to FIG. 1 and FIG. 2, a defect inspection system 1 according to some embodiments includes a first defect inspection apparatus 100, a stage 110, and a controller 195.

The first defect inspection apparatus 100 may be used to detect defects in the measurement target 10 (for example, defects in a pattern formed on a substrate) in a non-destructive manner in a semiconductor manufacturing process for manufacturing a semiconductor device.

The stage 110 is configured to receive the measurement target 10 thereon. The stage 110 may support the measurement target 10 thereon. For example, the stage may have a flat upper surface for receiving the measurement target 10. The stage 110 may be movable in a horizontal direction (e.g., a direction parallel to a surface of the measurement target 10) and/or in a vertical direction (e.g., a direction perpendicular to the surface of the measurement target 10) under an operation of a driving unit and may be rotatable in a predetermined direction. The stage 110 may be moved under the control of the controller 195. For example, the controller 195 may supply an electrical signal to a driving unit to cause the stage to move in a particular direction or rotate. The driving unit may be a linear actuator, an electric motor, or other type of mechanical drive.

The first defect inspection apparatus 100 includes a light source unit 20, a first beam splitter 170, an objective lens 180, and a first detector 190. The first defect inspection apparatus 100 may operate under the control of the controller 195.

The light source unit 20 is configured to output first incident light L1 and second incident light L2. The first incident light L1 and the second incident light L2 have different wavelengths. The wavelength of the first incident light L1 is shorter than the wavelength of the second incident light L2. For example, the first incident light L1 may be in the visible light band and the second incident light L2 may be in the infrared band.

The light source unit 20 may include a first light source 120 and an optical element 140.

The first light source 120 may output the first incident light L1. The first light source 120 may include, for example, a xenon plasma lamp, a fluorescent lamp, at least one light emitting element (LED), or a laser, etc.

The optical element 140 may receive the first incident light L1 and generate the second incident light L2 having a different wavelength from that of the first incident light L1 and a different frequency from that of the first incident light L1. For example, the optical element 140 may include a nonlinear optical material. The optical element 140 may include, for example, a crystal such as KTP (Potassium Titanyl Phosphate), LiNbO₃, PPLN (periodically poled LiNbO₃), KTN, KnbO₃, etc. For example, the optical element 140 may generate the second incident light L2 which may have a frequency two times the frequency of the first incident light L1 using a second-order nonlinear optical phenomenon. The second-order nonlinear optical phenomenon may include second harmonic generation (SHG), optical parametric process, etc. In addition, the optical element 140 may generate the second incident light L2 by adjusting the frequency of the first incident light L1 through various phenomena, various materials, or various devices.

The first beam splitter 170 may reflect the first incident light L1 and the second incident light L2 to the measurement target 10. The first beam splitter 170 may be embodied as a mirror, which may be partially reflective.

The objective lens 180 may be disposed between the first beam splitter 170 and the measurement target 10. The objective lens 180 may converge the first incident light L1 and the second incident light L2. The objective lens 180 may focus the first incident light L1 and the second incident light L2 onto the measurement target 10.

The measurement target 10 includes a plurality of layers 11 and 12. For example, the measurement target 10 may include the first layer 11 and the second layer 12 disposed under the first layer 11. The first layer 11 may include a first pattern P1, and the second layer 12 may include a second pattern P2. One or more layers may be further disposed between the first layer 11 and the second layer 12 and/or under the second layer 12. For convenience of description, an example in which the measurement target 10 includes the first layer 11 and the second layer 12 is described below.

The objective lens 180 may condense or focus the first incident light L1 on a surface of the first layer 11 (e.g., an upper surface of the first layer 11) and may condense or focus the second incident light L2 on a surface of the second layer 12 (e.g., an upper surface of the second layer 12). In this regard, the surface may mean the upper surface. The upper surface may be covered by another layer such that the surface does not need to be an external surface and may instead be an interface between two layers. A point at which the first incident light L1 is focused on the surface of the first layer 11 may coincide, in the vertical direction, with a point at which the second incident light L2 is focused on the surface of the second layer 12. The first defect inspection apparatus 100 may irradiate each of the first incident light L1 and L2 onto the same area in a plan view.

The first incident light L1 may reflect from the measurement target 10. The reflected first incident light is referred to as the first reflected light. For example, the first incident light may reflect from the upper surface of the first layer 11. The second incident light may reflect from the measurement target 10. For example, the second incident light may reflect from an upper surface of the second layer 12. The reflected second incident light is referred to as second reflected light.

The objective lens 180 may transmit therethrough first reflected light L1′ reflected from the surface of the first layer 11 and second reflected light L2′ reflected from the surface of the second layer 12. The first reflected light L1′ and the second reflected light L2′ having been transmitted through the objective lens 180 may be transmitted to the first beam splitter 170. The first beam splitter 170 may transmit the first reflected light L1′ and the second reflected light L2′ therethrough.

The first detector 190 may detect the first reflected light L1′ and the second reflected light L2′. The first detector 190 may detect the first reflected light L1′ and generate a first image as a surface image of the first layer 11 of the measurement target 10. The first detector 190 may detect the second reflected light L2′ and generate a second image as a surface image of the second layer 12.

The first detector 190 may include, for example, a charge-coupled device (CCD) camera or a complementary metal-oxide-semiconductor (CMOS) image sensor for detecting light in the visible spectrum and in the infrared spectrum.

The first defect inspection apparatus 100 may include one or more lenses. For example, the first defect inspection apparatus 100 may include a first lens 130 disposed between the first light source 120 and the optical element 140, and a second lens 132 disposed between the optical clement 140 and the first beam splitter 170. The first lens 130 may condense or focus the first incident light L1 which may be divergent. The second lens 132 may condense or focus each of the divergent incident light L1 and the second incident light L2 which may be divergent.

The light source unit 20 may simultaneously output the first incident light L1 and the second incident light L2. Accordingly, the first defect inspection apparatus 100 may simultaneously scan the first layer 11 and the second layer 12. The first defect inspection apparatus 100 may simultaneously generate the first image and the second image of the same area in a plan view.

The controller 195 may control the first defect inspection apparatus 100 and the stage 110. The controller 195 may perform an inspection based on the first image and the second image to determine if a defect occurs and/or which layer (for example, the first layer 11) of the measurement target 10 the defect occurs in. For example, the controller 195 may perform an inspection to determine whether a defect of the measurement target 10 is a surface defect that has occurred in the highest layer (e.g., the first layer 11) of the measurement target 10, or a buried defect that has occurred in a layer (for example, the second layer 12) disposed under the highest layer (e.g., the first layer 11) of the measurement target 10. Hereinafter, a surface defect may be referred to as a defect that has occurred in the first layer 11, and a buried defect may be referred to as a defect that has occurred in the second layer 12. If the controller 195 is unable to determine if the defect is a surface defect or a buried defect, the controller may identify the defect as a nonvisible defect.

The controller 195 may be implemented using hardware, firmware, software, or any combination thereof. For example, the controller 195 may be a computing device such as a workstation computer, a desktop computer, a laptop computer, or a tablet computer. The controller 195 may be a complex processor such as a microprocessor, CPU, GPU, etc., a processor configured using software, dedicated hardware, or firmware. The controller 195 may be implemented, for example, as a general-purpose computer or an application-specific hardware such as a digital signal processor (DSP), a field programmable gate array (FPGA), or an application specific integrated circuit (ASIC).

According to some embodiments, an operation of the controller 195 may be implemented based on instructions stored on a machine-readable medium that may be read and executed by the one or more processors. In this regard, the machine-readable medium may include any mechanism for storing and/or transmitting information in a form readable by a machine (e.g., a computing device). For example, the machine-readable medium may include read only memory (ROM), random access memory (RAM), magnetic disk storage media, optical storage media, flash memory devices, electrical, or optical storage devices. Alternatively, the controller 195 may be derived from another device that executes a computing device, a processor, firmware, software, routines, and instructions, etc.

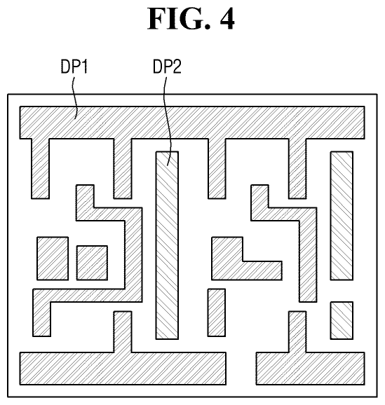

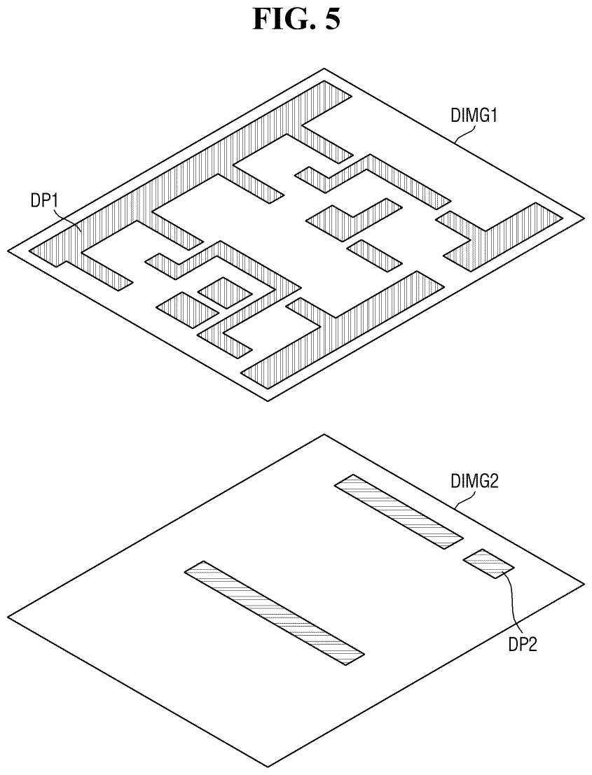

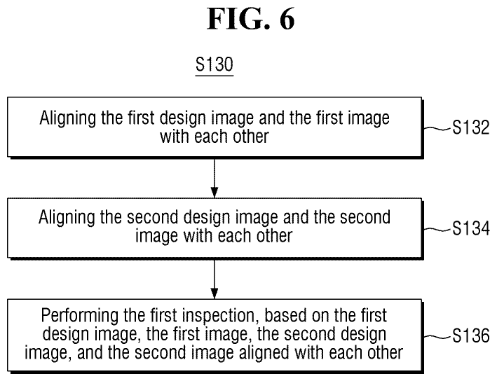

FIG. 3 is a flowchart illustrating a defect inspection method according to some embodiments. FIG. 4 and FIG. 5 are diagrams for describing the defect inspection method in FIG. 3. For reference, FIG. 4 is a plan view of FIG. 5.

Referring to FIGS. 1 to 5, a design image DIMG1 and DIMG2 of the measurement target 10 including the first layer 11 and the second layer 12 disposed under the first layer 11 may be obtained in S110.

The design image DIMG1 and DIMG2 may include the first design image DIMG1 of the first layer 11 and the second design image DIMG2 of the second layer 12. The first design image DIMG1 may include a first design pattern DP1, and the second design image DIMG2 may include a second design pattern DP2. The design image DIMG1 and DIMG2 may include a graphic data system (GDS) image as a storage format of a layout.

For example, the controller 195 may acquire the design image DIMG1 and DIMG2 of the measurement target 10. For example, the controller 195 may receive the design image DIMG1 and DIMG2 from data storage or an external source.

A first image generated by scanning the first layer 11 using the first incident light L1 and a second image generated by scanning the second layer 12 using the second incident light L2 may be obtained in S120.

For example, the controller 195 may cause the stage 110 to move to align the first defect inspection apparatus 100 and the measurement target 10 with each other and operate the first defect inspection apparatus 100. For example, controller may output a control signal to one or more driving units to move the stage horizontally to align the measurement target with the first defect inspection apparatus, and the controller 195 may output another control signal to one or more driving units to move the stage vertically to position the inspection target 10 in position for inspection. The first defect inspection apparatus 100 may generate the first image by scanning the first layer 11 using the first incident light L1 and may generate the second image by scanning the second layer 12 using the second incident light L2. The controller 195 may acquire the first image and the second image from the first defect inspection apparatus 100. The defect inspection apparatus 100 may scan the inspection target 10 by moving the stage 110 horizontally in a pattern while detecting the reflected light. For example, the controller 195 may send a control signal to one or more actuators to cause the stage 110 to move horizontally in the pattern. The first inspection apparatus 100 may scan the first layer 11 with the first incident light L1 and the second layer 12 with the second incident light L2 simultaneously.

In an example, S120 may be performed after S110. In another example, S120 may be performed before S110 or may be performed simultaneously with S110.

A first inspection may be performed to determine whether a defect of the measurement target 10 is a first defect that has occurred in the first layer 11, or a second defect that has occurred in the second layer 12. The first inspection may be performed based on the first design image DIMG1, the first image, the second design image DIMG2, and the second image in S130.

For example, the controller 195 may perform the first inspection to determine whether the defect of the measurement target 10 is a first defect that has occurred in the first layer 11, or a second defect that has occurred in the second layer 12, based on the first design image DIMG1, the first image, the second design image DIMG2, and the second image. As will be explained hereafter, the determination may be performed by comparing the images and the design images to find if the defect is present in one of the images.

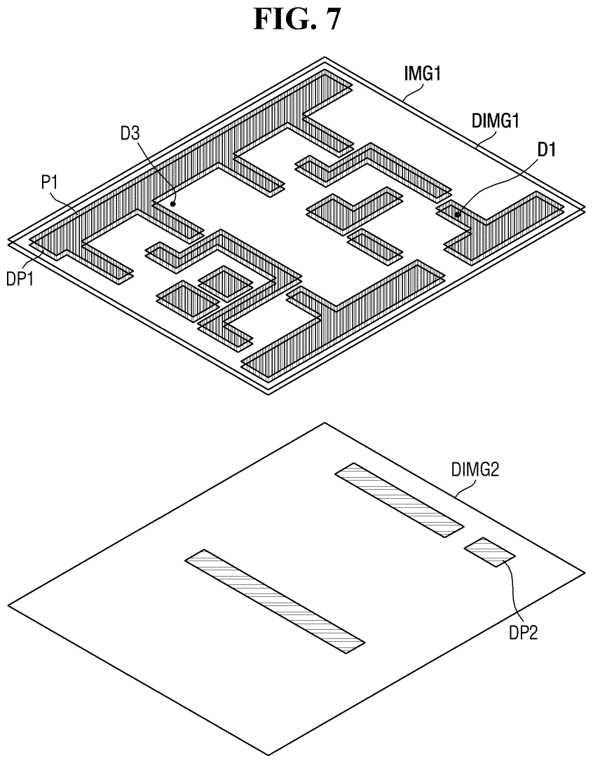

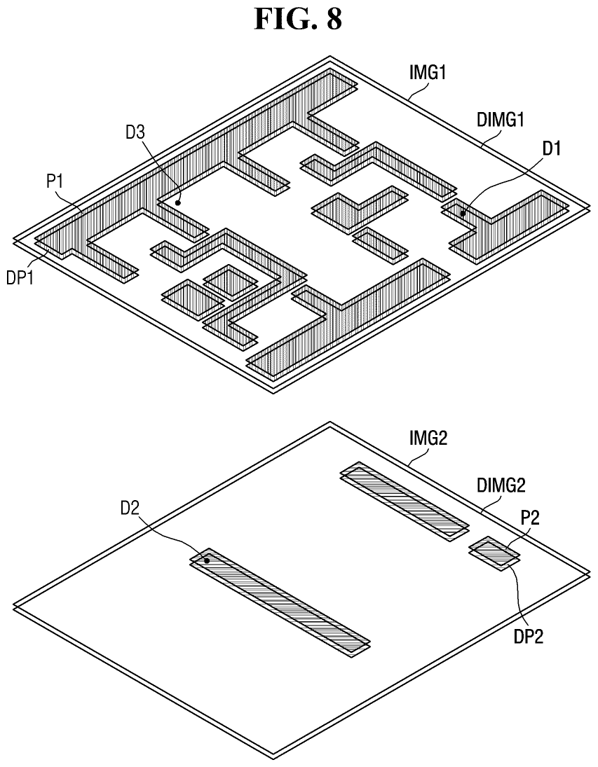

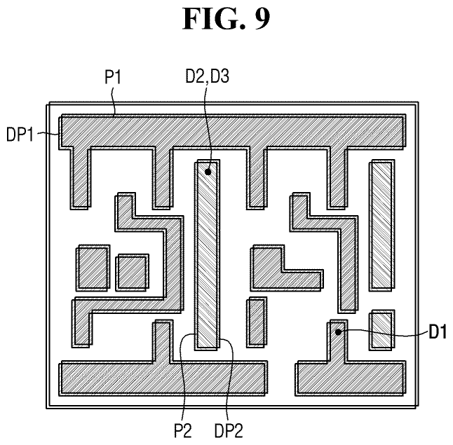

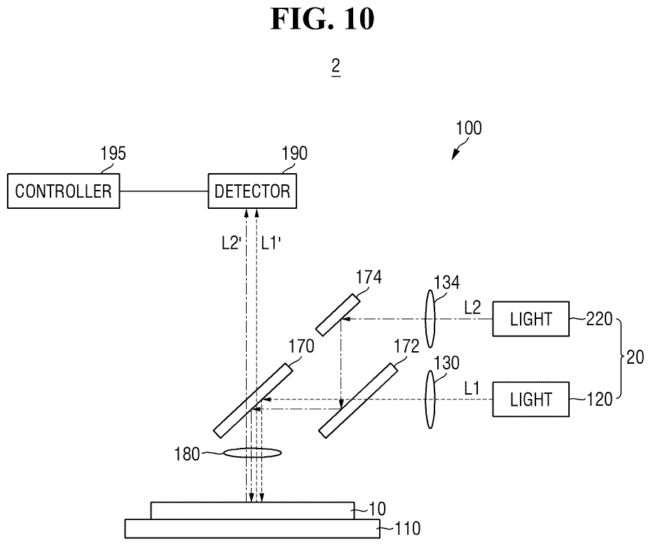

FIG. 6 is a flowchart for describing S130 in FIG. 4. FIG. 7 to FIG. 9 are diagrams for illustrating the defect inspection method in FIG. 6. For reference, FIG. 9 is a plan view of FIG. 8.

Referring to FIG. 1, FIG. 2, FIG. 6, and FIG. 7, the first design image DIMG1 and a first image IMG1 may be aligned with each other in S132. The first image IMG1 may be the first image acquired in S120 of FIG. 3.

For example, the first design image DIMG1 and the first image IMG1 may be of the same area, but may not be aligned with each other. The controller 195 may calculate an offset between the first design image DIMG1 and the first image IMG1 (for example, an offset between the first design pattern DP1 and a first pattern P1 corresponding to the first design pattern DP1). The offset may be determined by the controller 195 by comparing the location of a known feature in the first design image DIMG1 and the first image IMG1. For example, comparing the location of an external corner of pattern in each of the first design image DIMG1 and the first image IMG1. The controller 195 may align the first design image DIMG1 and the first image IMG1 with each other using the offset. The first design pattern DP1 may be aligned with the first pattern P1 corresponding to the first design pattern DP1.

In order to describe S130, an example is given in which the first image IMG1 includes defects D1 and D3.

Referring to FIG. 1, FIG. 2, FIG. 6, and FIG. 8, the second design image DIMG2 and a second image IMG2 may be aligned with each other in S134. The second image IMG2 may be the second image acquired in S120 of FIG. 3.

For example, the controller 195 may align the second design image DIMG2 and the second image IMG2 with each other. The second design image DIMG2 and the first design image DIMG1 may be of the same area and may be aligned with each other. The second image IMG2 and the first image IMG1 may be generated by scanning the same area and may be aligned with each other. The controller 195 may align the second design image DIMG2 and the second image IMG2 with each other using the offset between the first design image DIMG1 and the first image IMG1 as calculated in S132. Accordingly, the design images DIMG1 and DIMG2 and the first and second images IMG1 and IMG2 may be aligned with each other. The second design pattern DP2 may be aligned with a second pattern P2 corresponding to the second design pattern DP2.

In order to describe S130, an example is given in which the second image IMG2 includes defect D2.

Referring to FIG. 1, FIG. 2, FIG. 6, and FIG. 9, based on the first design image DIMG1, the first image IMG1, the second design image DIMG2, and the second image IMG2 which are each aligned with each other, the first inspection may be performed in S136.

The controller 195 may perform the first inspection based on the first design image DIMG1 aligned with the first image IMG1, and the second design image DIMG2 aligned with the second image IMG2. The first defect D1 of the first image IMG1 is disposed on the first pattern P1 which corresponds to the first design pattern DP1. Therefore, the controller 195 may determine that the first defect D1 of the first image IMG1 is a defect that has occurred in the first layer 11. The third defect D3 of the first image IMG1 is not disposed on the first pattern P1. The second defect D2 of the second image IMG2 overlaps the third defect D3 of the first image IMG1 in a plan view and is disposed on the second pattern P2 which corresponds to the second design pattern DP2. Therefore, the controller 195 may determine that the second defect D2 of the second image IMG2 is a defect that has occurred in the second layer 12 and that the third defect D3 of the first image IMG1 is due to a defect that has occurred in the second layer 12.

As described, a defect in a lower layer may cause a defect to appear in an upper layer. For example, the second defect D2 in the second layer 12 caused the third defect D3 to appear in the first layer 11. In some embodiments, by identifying which layer the defect first appears in, the controller 195 may determine which layer is responsible for causing the defect.

In addition, when the measurement target 10 includes a plurality of layers under the second layer 12, the method may include not only determining whether the defect of the measurement target 10 is a surface defect or a buried defect, but also determining which layer a defect causing the third defect D3 of the first image IMG1 has occurred, based on an image generated by scanning at least one of the plurality of layers. For example, S110 may further include moving the stage vertically so that the second light is focused on a lower layer, acquiring a third design image of at least one lower layer among the plurality of layers, and S120 may further include acquiring a third image generated by scanning the at least one lower layer, and S130 may further include determining which layer (e.g., the first layer 11, the second layer 12, or the at least one layer) in which a defect causing the third defect D3 of the first image IMG1 has occurred, based on the first design image DIMG1, the first image IMG1, the second design image DIMG2, the second image IMG2, and the first image.

When detecting the defect in the measurement target 10 using incident light in the visible light band, the incident light in the visible light band cannot transmit through the measurement target 10, and thus the visible light band can be used to scan the surface of the measurement target 10 but cannot be used to scan an underlying layer of the measurement target 10. Therefore, without the second incident light, the first defect D1 of the first image IMG1 may be determined to be a defect that has occurred in the first layer 11 even when the defect is the result of a buried defect. Thus, the visible light band may not be useful for determining whether the third defect D3 of the first image IMG1 is a defect that has occurred in the first layer 11 or a defect caused by a defect that has occurred in the second layer 12.

However, the defect inspection method according to some embodiments may determine whether the defect of the measurement target 10 is a defect caused by the first layer 11 or a defect caused by the second layer 12, based on the first image IMG1 of the first layer 11 and the second image IMG2 of the second layer 12 of the measurement target 10. Therefore, the defect inspection may be performed at a higher precision.

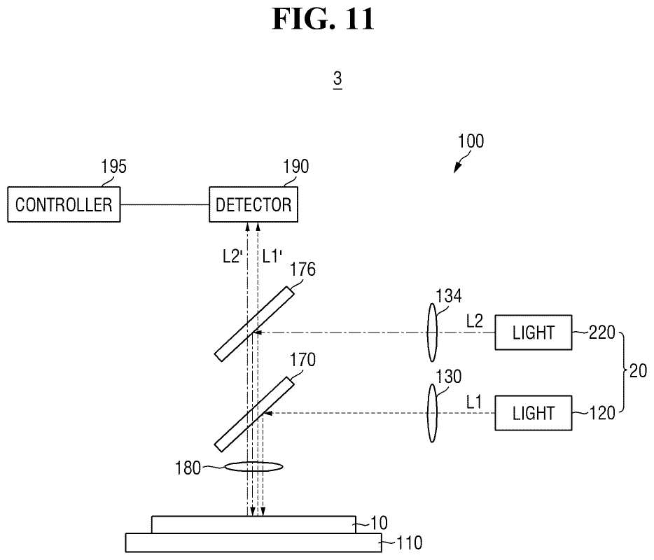

FIG. 10 is a diagram illustrating a defect inspection system according to some embodiments. For convenience of description, descriptions of components that are the same as, or similar to those described previously with reference to FIGS. 1 to 9 may be omitted or simply described.

Referring to FIG. 10, in a defect inspection system 2 according to some embodiments, the first defect inspection apparatus 100 may further include a second light source 220, a second beam splitter 172, and a third beam splitter 174.

The light source unit 20 may include a first light source 120 that outputs the first incident light L1 and a second light source 220 that outputs the second incident light L2. The second light source 220 may include, for example, a xenon plasma lamp, a fluorescent lamp, at least one light emitting element, or a laser.

The second beam splitter 172 may be disposed between the first light source 120 and the first beam splitter 170. The second beam splitter 172 may transmit the first incident light L1 therethrough. The second beam splitter 172 may provide the first incident light L1 to the first beam splitter 170. The second beam splitter 172 may be embodied as a mirror, which may be partially reflective.

The third beam splitter 174 may reflect the second incident light L2 to the second beam splitter 172. The second beam splitter 172 may reflect the second incident light L2 reflected from the third beam splitter 174 to the first beam splitter 170. The third beam splitter 174 may be embodied as a mirror, which may be partially reflective.

The first defect inspection apparatus 100 may include lenses 130 and 134. For example, the third lens 134 may be disposed between the second light source 220 and the third beam splitter 174. The third lens 134 may condense the second incident light L2 which may be divergent.

The positions of the first light source 120 and the second light source 122 are not limited thereto, and the positions of the first light source 120 and the second light source 220 may vary.

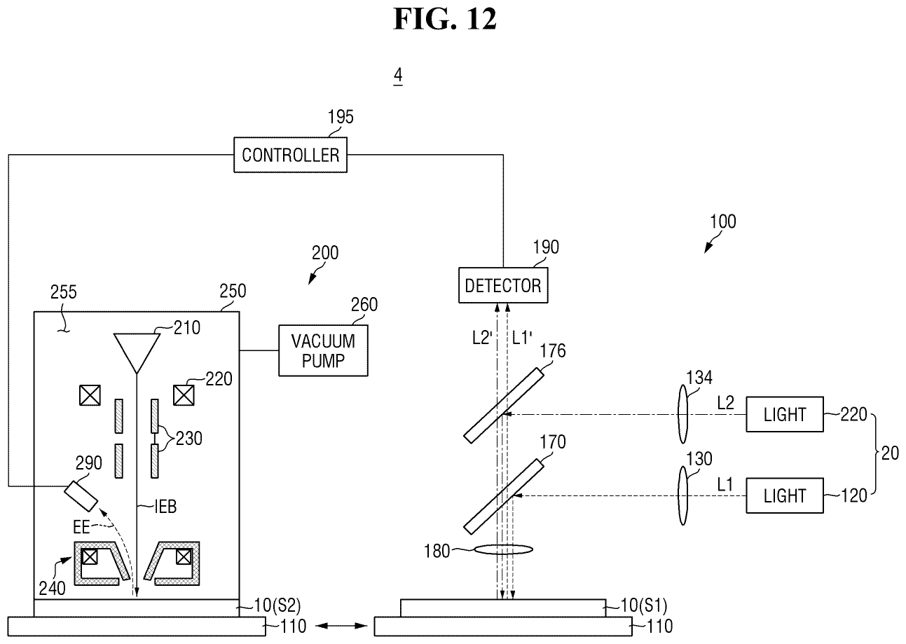

FIG. 11 is a diagram for illustrating a defect inspection system according to some embodiments. For convenience of description, descriptions of components that are the same as, or similar to those described previously with reference to FIGS. 1 to 9 may be omitted or simply described.

Referring to FIG. 11, in a defect inspection system 3 according to some embodiments, the first defect inspection apparatus 100 may further include the second light source 122 and a fourth beam splitter 176.

Descriptions of the second light source 122 and the third lens 134 may be the same as those set forth above using FIG. 10.

The fourth beam splitter 176 may be disposed between the first beam splitter 170 and the first detector 190. The fourth beam splitter 176 may reflect the second incident light L2 to the first beam splitter 170. The fourth beam splitter 176 may receive the first reflected light L1′ and the second reflected light L2′ from the first beam splitter 170. The fourth beam splitter 176 may transmit the first reflected light L1′ and the second reflected light L2′ therethrough. The fourth beam splitter 176 may be embodied as a mirror, which may be partially reflective.

The positions of the first light source 120 and the second light source 122 are not limited thereto, and the positions of the first light source 120 and the second light source 122 may vary.

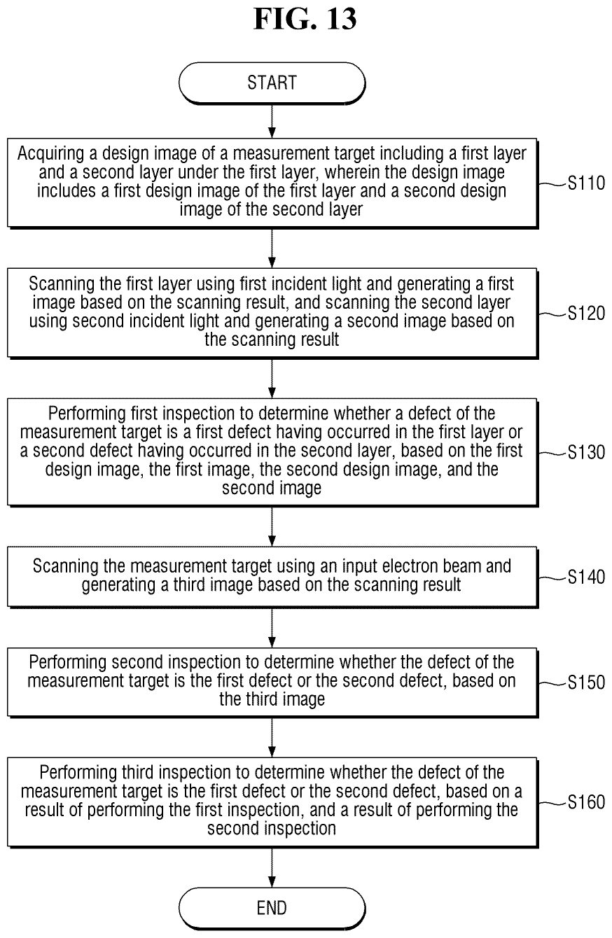

FIG. 12 is a diagram illustrating a defect inspection system according to some embodiments. For convenience of description, descriptions of components that are the same as, or similar to those described previously with reference to FIGS. 1 to 9 may be omitted or simply described.

Referring to FIG. 12, a defect inspection system 4 according to some embodiments may further include a second defect inspection apparatus 200. The defect inspection system 4 may include the first defect inspection apparatus 100 in FIG. 1, the first defect inspection apparatus 100 in FIG. 10, or the first defect inspection apparatus 100 in FIG. 11.

The second defect inspection apparatus 200 may include an electron gun 210, a focusing lens 220, a deflector 230, a second objective lens 240, a vacuum pump 260, and a second detector 290.

A vacuum chamber 250 may provide an inspection space 255. The inspection space 255 may be maintained in a vacuum state. For this purpose, the vacuum pump 260 connected to the inspection space 255 may be provided (e.g., the vacuum pump 260 may pump gas from the inspection space 255 to generate the vacuum state). The measurement target 10 may be received within the vacuum chamber 250.

The electron gun 210 may generate and emit an input electron beam IEB. A wavelength of the input electron beam IEB may be determined based on energy of electrons emitted from the electron gun 210. According to some embodiments, the wavelength of the input electron beam IEB may be several nanometers. According to some embodiments, the electron gun 210 may be of one of a cold field emission (CFE) type, a Schottky emission (SE) type, and a thermionic emission (TE) type.

The electron gun 210 thermally or electrically applies energy greater than or equal to a work function (i.e., a difference between an energy level in a vacuum and the Fermi energy) to electrons contained in a solid material as an electron source, thereby generating the input electron beam IEB.

The focusing lens 220 may be disposed on a path of the input electron beam IEB and between the electron gun 210 and the measurement target 10. According to some embodiments, the focusing lens 220 may focus the input electron beam IEB on the deflector 230. Accordingly, controllability of the input electron beam IEB by the deflector 230 may be improved.

The deflector 230 may be disposed on a path of the input electron beam IEB and between the focusing lens 220 and the measurement target 10. The deflector 230 may deflect the input electron beam IEB emitted from the electron gun 210. The deflector 230 may deflect the input electron beam IEB so that the input electron beam IEB travels through the focusing lens 220 and the second objective lens 240 and is irradiated to a set position on the measurement target 10. According to some embodiments, the deflector 230 may scan the input electron beam IEB onto measurement target 10. The deflector 230 may be either of an electric type or a magnetic type. Thus, the measurement target 10 may remain stationary and the electron beam IEB scanned in a pattern across the measurement target 10 through the use of the deflector 230.

The second objective lens 240 may be disposed on the path of the input electron beam IEB and between the deflector 230 and the measurement target 10. The second objective lens 240 may focus the input electron beam IEB onto the measurement target 10.

The second defect inspection apparatus 200 may further include additional focusing lenses and/or an additional deflector.

The second detector 290 may detect emission electrons EE emitted from the measurement target 10 in response to the input electron beam IEB. The second detector 290 may detect the emission electrons EE and generate a third image based on the detection result. Alternatively, the controller 195 may generate the third image based on the emission electrons EE detected by the second detector 290. The third image may be a voltage contrast image (VC image).

The controller 195 may control the second defect inspection apparatus 200. For example, the controller 195 may send a control signal to the electron gun 210, the focusing lens 220, and/or the deflector 230, to scan the input electron beam across the measurement target 10. Based on the third image, the controller 195 may inspect whether the defect of the measurement target 10 is the first defect that has occurred in the first layer 11 or the second defect that has occurred in the second layer 12.

The stage 110 may move to a first position S1 and a second position S2 under the control of the controller 195. When the stage 110 is at the first position S1, the measurement target 10 may receive the first incident light L1 and the second incident light L2 from the first defect inspection apparatus 100. When the stage 110 is at the second position S2, the measurement target 10 may receive the input electron beam IEB from the second defect inspection apparatus 200.

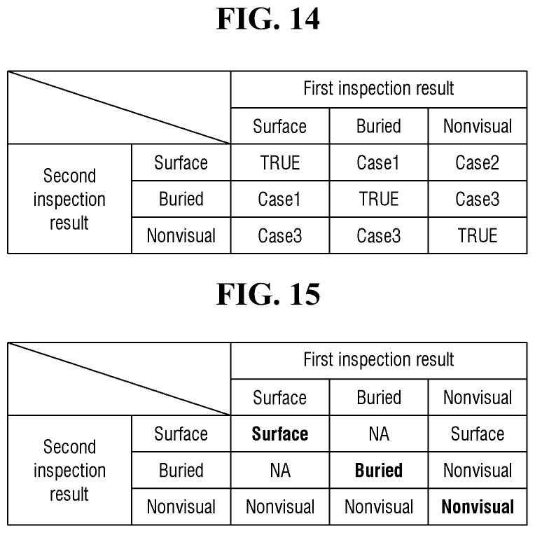

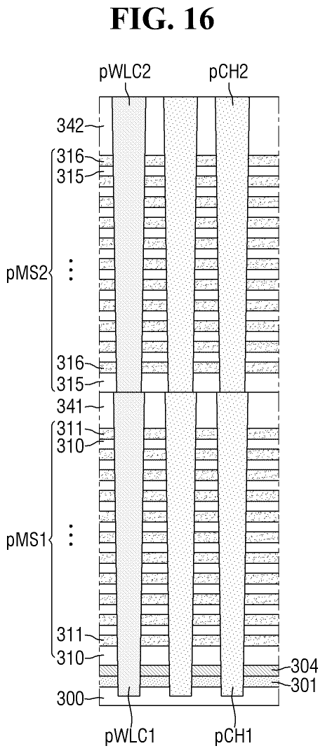

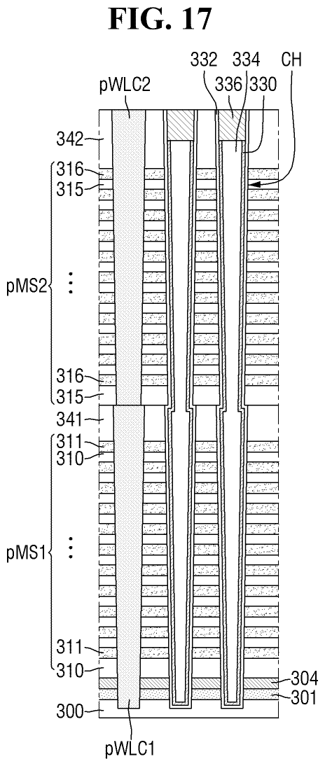

FIG. 13 is a flowchart illustrating a defect inspection method according to some embodiments. FIG. 14 and FIG. 15 are diagrams for illustrating the defect inspection method in FIG. 13. For convenience of description, contents duplicate with those described above with reference to FIGS. 1 to 9 are simply described or descriptions thereof are omitted.

Referring to FIG. 2, FIG. 12, and FIG. 13, the third image may be acquired by scanning the measurement target 10 using the input electron beam IEB in S140.

For example, the controller 195 may cause an actuator to move the stage 110 to the second position S2. The controller 195 may drive the stage 110 to align the second defect inspection apparatus 200 and the measurement target 10 with each other and operate the second defect inspection apparatus 200. The second defect inspection apparatus 200 may generate the third image by scanning the measurement target 10 using the input electron beam IEB.

The second inspection may be performed to determine whether a defect of the measurement target 10 is a first defect that has occurred in the first layer 11 or a second defect that has occurred in the second layer 12, based on the third image in S150.

For example, the controller 195 may perform the second inspection to determine whether the defect of the measurement target 10 is the first defect that has occurred in the first layer 11 or the second defect that has occurred in the second layer 12, based on the third image (i.e., a voltage contrast image). For example, the controller 195 may determine whether the defect of the measurement target 10 is the first defect that has occurred in the first layer 11 or the second defect that has occurred in the second layer 12, based on the gray scale level of the voltage contrast image.

A third inspection may be performed to determine whether the defect of the measurement target 10 is a first defect that has occurred in the first layer 11 or a second defect that has occurred in the second layer 12, based on the result of the first inspection performed in S130 and the result of the second inspection performed in S150 in S160.

For example, referring to FIG. 2 and FIG. 12 to FIG. 14, the controller 195 may generate a truth table of the first inspection result and the second inspection result. The first inspection result and the second inspection result may each include an indication of whether a defect is one of a first defect (i.e., a Surface defect) that has occurred in the first layer 11, a second defect (i.e., a Buried defect) that has occurred in the second layer 12, or a third defect (e.g., a Nonvisual defect) that cannot be identified is true or false. The truth table may include various values TRUE, Case1, Case2, Case3 depending on whether each of the first inspection result and the second inspection result is true or false. In the truth chart of FIG. 14, “TRUE” indicates that both inspections return the same result, Case1 indicates that the defect is not both the first defect and the second defect, Case2 indicates that the defect is a surface defect, and Case3 indicates that the defect is a nonvisual defect. The truth table may be represented as a data structure in the memory of the controller.

For example, referring to FIG. 14, the first inspection result may return a result of “Surface” when the defect is identified as occurring at the surface, a result of “Buried” when the defect is identified as occurring at a lower layer, or “Nonvisual” when the defect cannot be determined to be at the surface or at a lower layer. Similarly, the second inspection result may return a result of “Surface” when the defect is identified as occurring at the surface, a result of “Buried” when the defect is identified as occurring at a lower layer, or “Nonvisual” when the defect cannot be determined to be at the surface or at a lower layer. The truth table of FIG. 14 gives a result that can be found at the intersection of a column corresponding to the first inspection result and a row corresponding to the second inspection result. For example, if the first inspection result were “Surface” and the second inspection result were “Nonvisual”, the result would be Case3. As another example, if the first inspection result were “Surface” and the second inspection result were “Buried”, the result would be Case1. For example, referring to FIG. 2 and FIG. 12 to FIG. 15, the controller 195 may determine whether the defect of the measurement target 10 is the first defect “Surface”, the second defect “Buried”, the defect “Nonvisual” that cannot be identified, or is not both the first defect and the second defect NA, based on the truth table in FIG. 14

For example, S120 and S130 may be performed before sS140 and S150.

In another example, S120 and S130 may be performed after S140 and S150. Based on a result of performing S140 and S150 to perform the second inspection, a position at which the defect has occurred on the surface of the measurement target 10 may be determined. Subsequently, S120 and S130 may be performed on the position where the defect has occurred in the second inspection to review the result of the second inspection.

The defect inspection method according to some embodiments may inspect the defect of the measurement target 10 through the first inspection using the first incident light L1 and the second incident light L2 and the second inspection using the input electron beam IEB, such that the consistency of the defect inspection may be improved.

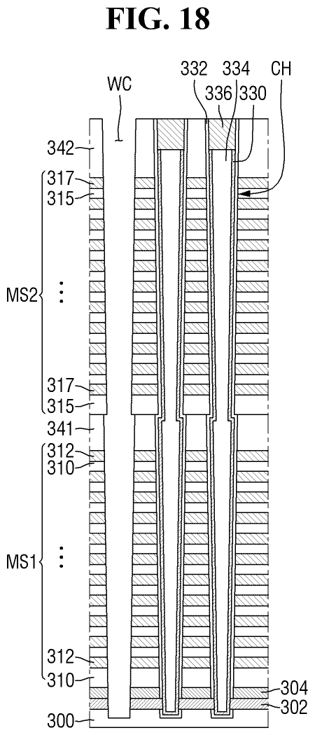

FIGS. 16 to 18 are cross-sectional views illustrating a semiconductor device manufacturing method according to some embodiments.

Referring to FIG. 16, a source sacrificial layer 301, a source support layer 304, a first pre-mold pMS1, a first pre-channel pCH1, and a first pre-word line cutting structure pWLC1 may be formed on a cell substrate 300. The source sacrificial layer 301 may include, for example, silicon nitride, silicon oxide, or silicon oxynitride. The first pre-mold pMS1 may be formed on an entire surface of the cell substrate 300. The first pre-mold pMS1 may include a plurality of first mold insulating films 310 and a plurality of first mold sacrificial films 311 that are alternately stacked on top of each other while being disposed on the cell substrate 300. A first interlayer insulating film 341 covering the first pre-mold pMS1 may be formed on the cell substrate 300. The first pre-word line cutting structure pWLC1 and the first pre-channel pCH1 may extend through the first pre-mold pMS1, the source support layer 304, and the source sacrificial layer 301 so as to contact the cell substrate 300.

A second pre-mold pMS2, a second pre-channel pCH2, and a second pre-word line cutting structure pWLC2 may be formed on the first pre-mold pMS1. The second pre-mold pMS2 may include a plurality of second mold insulating films 315 and a plurality of second mold sacrificial films 316 alternately stacked on top of each other while being disposed on the first pre-mold pMS1. A second interlayer insulating film 342 may be formed so as cover the second pre-mold pMS2. The second pre-channel pCH2 and the second pre-word line cutting structure pWLC2 may extend through the second interlayer insulating film 342 and the second pre-mold pMS2 so as to contact the first pre-channel pCS1 and the first pre-word line cutting structure pWCL1, respectively.

Each of the first mold insulating films 310 and the second mold insulating films 315 may include a silicon oxide film, and each of the first mold sacrificial films 311 and the second mold sacrificial films 316 may include a silicon nitride film. For example, each of the first pre-channel pCH1 and the second pre-channel pCH2 may include poly silicon (poly Si). Each of the first and second pre-word line cutting structures pWLC1 and pWLC2 may include a different material from that of each of the first and second pre-channels pCH1 and pCH2.

Referring to FIG. 17, the first pre-channel pCH1 and the second pre-channel pCH2 may be removed and a channel structure CH may be formed. The channel structure CH may include a semiconductor pattern 330, an information storage film 332, a filling pattern 334, and a channel pad 336. The information storage film 332, the semiconductor pattern 330, and the filling pattern 334 may be sequentially stacked in a channel hole formed by removing the first pre-channel pCH1 and the second pre-channel pCH2. Each of the information storage film 332 and the semiconductor pattern 330 may extend conformally along a profile of the channel hole. The filling pattern 334 may fill an area of the channel hole remaining after the information storage film 332 and the semiconductor pattern 330 fill the channel hole. The channel pad 336 may be electrically connected to a top of the semiconductor pattern 330.

The semiconductor pattern 330 may include, but is not limited to, a semiconductor material such as single crystal silicon, polycrystalline silicon, an organic semiconductor material, and a carbon nanostructure. The information storage film 332 may include a tunnel insulating film, a charge storage film, and a blocking insulating film that are sequentially stacked on an outer surface of the semiconductor pattern 330. Each of the tunnel insulating film and the blocking insulating film may include silicon oxide or a high dielectric constant material having a higher dielectric constant than that of silicon oxide. The high dielectric constant material may include aluminum oxide (Al₂O₃) or hafnium oxide (HfO₂). The charge storage film may include, for example, silicon nitride.

Referring to FIG. 18, the first and second pre-word line cutting structures pWLC2 may be removed to form a word line cutting area WC. The first and second mold sacrificial films 311 and 316 exposed through the word line cutting area WC may be selectively removed. A first gate electrode 312 may be formed in an area where each first mold sacrificial film 311 has been removed, and a second gate electrodes 317 may be formed in an area where each second mold sacrificial films 316 has been removed. Accordingly, first and second mold structures MS1 and MS2 may be formed. Additionally, a source layer 302 may be formed in an area where the source sacrificial layer 301 has been removed. At this time, the source layer 302 may extend through the information storage film 332 so as to contact a side surface of the semiconductor pattern 330.

Subsequently, the defect inspection method as described above may be performed with reference to FIGS. 1 to 15.

For example, a first image may be generated by scanning the second interlayer insulating film 342, and a second image may be generated by scanning the first interlayer insulating film 341. Based on the first image and the second image, it may be determined whether a defect of the first image is a defect that has occurred in the second interlayer insulating film 342 or a defect that is caused by a defect which has occurred in a layer under the second interlayer insulating film 342. Additionally, a plurality of layers (e.g., a bottom second gate electrode 317, a top first gate electrode 312, the source layer 302, etc.) disposed under the second interlayer insulating film 342 may be scanned to generate a plurality of images. Based on the plurality of images, a layer in which a defect causing the defect of the first image has occurred may be determined. In other words, a layer in which the defect of the first image has occurred may be determined.

Based on the determination result, various conditions of the semiconductor process may be changed. Then, a semiconductor device in FIG. 18 may be manufactured again based on the changed conditions. This process may be repeated until the defect of the semiconductor device satisfies a set condition.

A subsequent process may then be performed to manufacture the semiconductor device.

Although embodiments of the present disclosure have been described with reference to the accompanying drawings, embodiments of the present disclosure are not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A defect inspection system, comprising:
a stage configured to receive a measurement target thereon, wherein the measurement target includes a first layer and a second layer disposed under the first layer; and
a defect inspection apparatus, including:
a light source unit configured to output first incident light and second incident light;
a beam splitter configured to reflect the first incident light and the second incident light from the light source unit to the measurement target, and transmit first reflected light and second reflected light therethrough, wherein the first reflected light corresponds to the first incident light reflected from the first layer, and the second reflected light corresponds to the second incident light reflected from the second layer;
an objective lens between the beam splitter and the measurement target; and
a detector configured to:
detect the first reflected light and generate a first image of the first layer based on the detected first reflected light; and
detect the second reflected light and generate a second image of the second layer based on the detected second reflected light,
wherein the first incident light is included in a visible light band, and
wherein the second incident light is included in an infrared light band.

2. The defect inspection system of claim 1, wherein the light source unit is configured to simultaneously output the first incident light and the second incident light.

3. The defect inspection system of claim 1, wherein the light source unit includes:
a light source configured to output the first incident light; and
an optical element configured to non-linearly convert the first incident light into the second incident light.

4. The defect inspection system of claim 1, wherein the light source unit includes:
a first light source configured to output the first incident light; and
a second light source configured to output the second incident light.

5. The defect inspection system of claim 4, wherein the beam splitter is a first beam splitter, further comprising:
a second beam splitter between the first light source and the first beam splitter; and
a third beam splitter configured to reflect the second incident light of the second light source to the second beam splitter.

6. The defect inspection system of claim 4, wherein the beam splitter is a first beam splitter, further comprising a second beam splitter between the first beam splitter and the detector, and the second beam splitter is configured to reflect the second incident light from the second light source to the first beam splitter.

7. The defect inspection system of claim 1, further comprising a controller configured to determine whether a defect of the first image is a surface defect originating from the first layer or a buried defect originating from a portion under the first layer, based on the first image and the second image.

8. The defect inspection system of claim 7, wherein the controller is configured to:
align a first design image of the first layer and the first image with each other;
align a second design image of the second layer and the second image with each other, based on the first design image aligned with the first image; and
determine whether the defect of the first image is the surface defect or the buried defect, based on the first design image, the first image, the second design image, and the second image aligned with each other.

9. The defect inspection system of claim 1, wherein the defect inspection apparatus is a first defect inspection apparatus, the objective lens is a first objective lens, and the detector is a first detector, the defect inspection system further comprising a second defect inspection apparatus,
wherein the second defect inspection apparatus includes:
an electron gun configured to output an input electron beam;
a second objective lens between the electron gun and the stage, and
a second detector,
wherein the stage is configured to be movable to a first position and a second position,
wherein when the stage is at the first position, the measurement target receives the first incident light and the second incident light from the first defect inspection apparatus, and
wherein when the stage is at the second position, the measurement target receives the input electron beam from the second defect inspection apparatus, and the second detector is configured to receive emission electrons emitted from the measurement target in response to the input electron beam and to detect and generate a third image based on the received emission electrons.

10. The defect inspection system of claim 9, further comprising a controller configured to determine whether a defect of the first image is a surface defect of the first layer or a buried defect originating from a portion under the first layer, based on the first image, the second image, and the third image.

11. A defect inspection system comprising:
a stage configured to receive a measurement target thereon, wherein the measurement target includes a first layer and a second layer disposed under the first layer;
a defect inspection apparatus configured to scan a surface of the first layer using first incident light and generate a first image based on the scanning result, and to scan a surface of the second layer using second incident light and generate a second image based on the scanning result; and
a controller configured to determine whether a defect of the measurement target is a first defect having occurred in the first layer or a second defect having occurred in a portion under the first layer, based on a first design image for the first layer, the first image, a second design image of the second layer, and the second image,
wherein the first incident light and the second incident light have different wavelengths.

12. The defect inspection system of claim 11, wherein the defect inspection apparatus is configured to simultaneously scan the surface of the first layer and the surface of the second layer.

13. The defect inspection system of claim 11, wherein the defect inspection apparatus includes a first light source configured to output the first incident light and the defect inspection apparatus is configured to non-linearly convert the first incident light to generate the second incident light.

14. The defect inspection system of claim 11, wherein the defect inspection apparatus includes a first light source configured to output the first incident light, and a second light source configured to output the second incident light.

15. The defect inspection system of claim 11, wherein the defect inspection apparatus is a first defect inspection apparatus, further comprising a second defect inspection apparatus configured to scan the measurement target using an input electron beam and generate a third image based on the scanning result,
wherein the controller is configured to determine whether the defect of the measurement target is the first defect or the second defect, based on the third image.

16. A method of manufacturing a semiconductor device, comprising:
fabricating a portion of a semiconductor device to generate a measurement target;
acquiring a design image of the measurement target including a first layer and a second layer under the first layer, wherein the design image includes a first design image of the first layer and a second design image of the second layer;
scanning the first layer using first incident light and generating a first image based on the scanning result, and scanning the second layer using second incident light and generating a second image based on the scanning result;
performing an inspection to determine whether a defect of the measurement target is a first defect having occurred in the first layer or a second defect having occurred in the second layer, based on the first design image, the first image, the second design image, and the second image; and
verifying the defects of the semiconductor device based on results of the inspection.

17. The manufacturing method of claim 16, wherein the performing of the inspection includes:
aligning the first design image and the first image with each other;
aligning the second design image and the second image with each other using the first design image and the first image; and
determining whether a defect of the measurement target is a first defect or a second defect, based on the first design image, the first image, the second design image, and the second image aligned with each other.

18. The manufacturing method of claim 16, wherein a wavelength of the first incident light is shorter than a wavelength of the second incident light.

19. The manufacturing method of claim 16, wherein the first incident light is included in a visible light band, and
wherein the second incident light is included in an infrared-ray band.

20. The manufacturing method of claim 16, wherein the inspection is a first inspection, the method further comprising:
scanning the measurement target using an input electron beam and generating a third image based on the scanning result;
performing second inspection to determine whether the defect of the measurement target is the first defect or the second defect, based on the third image; and
performing third inspection to determine whether the defect of the measurement target is the first defect or the second defect, based on a result of performing the first inspection, and a result of performing the second inspection.
